(19) United States
(12) Patent Application Publication
(10) Pub. No.: US 2026/0271264 A1
(43) Pub. Date: Sep. 10, 2026

(54) DRAM and 3D DRAM Devices and Their Forming Methods

(71) Applicant: QEMS, Inc., Sedona, AZ (US)

(72) Inventors: Vinod Purayath, Sedona, AZ (US); Kenta Ohama, Tokyo (JP)

(21) Appl. No.: 19/070,330

(22) Filed: Mar. 4, 2025

(51) Int. Cl. H10B 12/00; G11C 11/4091

(52) U.S. Cl. CPC H10B 12/30; G11C 11/4091; H10B 12/03; H10B 12/05; H10B 12/50

(57) ABSTRACT

A DRAM device includes a substantially vertical bitline. A channel is at a first elevational level above a substrate and on a side of the bitline. A capacitor is electrically connected to the channel. A wordline is at a second elevational level above the substrate and on the side of the bitline, the wordline being elevationally either above or below the channel. A combination of the substantially vertical bitline, the channel, the capacitor, and the wordline provide at least a part of a memory cell. The memory cell may be a double-bit memory cell. The capacitor may include a primary capacitor electrode forming at least one container structure that has an open side with a secondary capacitor electrode extending to within the container structure. A DRAM forming method may include simultaneously forming first and second wordlines, first and second bitlines, first and second channels, and/or first and second capacitors.

### BACKGROUND

Historically, dynamic random access memory (DRAM) devices relied on two-dimensional (2D) arrays of memory cells as the architecture of choice. Because 2D arrays are formed at one elevational level, limits exist to the density of memory cells per unit area on the surface of an underlying substrate. Numerous attempts have been made to shift DRAM to a three-dimensional (3D) architecture. Generally, the concepts to date involve stacking existing 2D architecture. However, stacking existing 2D architecture still exhibits density limitations and carries over the same device performance levels from known 2D architecture.

Accordingly, a 3D architecture that departs from the structures used in 2D architecture and that can take advantage of higher performance materials would be beneficial.

### SUMMARY

A dynamic random access memory (DRAM) device includes a bitline that is substantially vertical with respect to a substrate along the bitline's longest dimension. A channel is at a first elevational level above and separated from the substrate and is on a side of and electrically connected to the bitline. A capacitor is electrically connected to the channel. A wordline is at a second elevational level above and separated from the substrate on the side of and electrically insulated from the bitline, the wordline being elevationally either above or below the channel. A combination of the substantially vertical bitline, the channel, the capacitor, and the wordline provide at least a part of a memory cell.

Another DRAM device includes a substrate and a bitline. A first channel and a second channel are both at a first elevational level above the substrate on opposing sides of and electrically connected to the bitline. A first capacitor is electrically connected to the first channel and a second capacitor is electrically connected to the second channel. A first wordline and a second wordline are both at a second elevational level above the substrate on opposing sides of and electrically insulated from the bitline. The first and second wordlines are elevationally either above or below the first and second channels, respectively. A combination of the bitline, the first and second channels, the first and second capacitors, and the first and second wordlines provide a double-bit memory cell.

A further DRAM device includes a substrate and a bitline. A channel is at a first elevational level above the substrate and is on a side of and electrically connected to the bitline. A capacitor is at the first elevational level lateral from and electrically connected to the channel. The capacitor includes a primary capacitor electrode electrically connected to the channel, the primary capacitor electrode forming one or more container structures that have an open side. A secondary capacitor electrode extends to within the one or more container structures. A capacitor dielectric is between the primary and secondary capacitor electrodes. A wordline is at a second elevational level above the substrate on the side of and electrically insulated from the bitline. A combination of the bitline, the channel, the capacitor, and the wordline provide at least a part of a memory cell.

A DRAM device forming method includes forming first and second layers of channel material at respective first and second increasing elevational levels above a substrate. First and second wordlines are formed at respective third and fourth increasing elevational levels above the substrate. A bitline is formed through the first and second layers of channel material, the first and second wordlines being on a side of and electrically insulated from the bitline. First and second channels are formed from the respective first and second layers of channel material. The first and second channels are on the side of and electrically connected to the bitline. The first and second wordlines are elevationally either above or below the respective first and second channels. First and second capacitors are formed electrically connected to the respective first and second channels. A combination of the bitline, the first and second channels, the first and second capacitors, and the first and second wordlines provide at least a part of respective first and second memory cells, thus providing a column of memory cells. In one implementation, the method includes simultaneously forming the first and second wordlines. In another implementation, the method includes simultaneously forming the first and second channels. In a further implementation, the method includes simultaneously forming the first and second capacitors.

The features, functions, and advantages that have been discussed can be achieved independently in various embodiments or may be combined in yet other embodiments further details of which can be seen with reference to the following description and drawings.

### BRIEF DESCRIPTION OF THE DRAWINGS

Some embodiments are described below with reference to the following accompanying drawings.

FIG. 1 is a conceptual schematic of a memory cell.

FIG. 2 is a conceptual, top view of selected components in a portion of a memory array.

FIG. 3 is a conceptual, isometric view of the memory cell in FIG. 1 arranged in a memory array.

FIG. 4 is a flow diagram of a DRAM device forming method.

FIGS. 5A-C to 14A-C illustrate partial, cross-sectional views of a portion of a memory array at successive process steps.

FIG. 15A-C illustrate partial, cross-sectional views of a memory array according to one example of single fin capacitors at a process step subsequent to the process step shown in FIGS. 14A-C.

FIGS. 16A-C to 19A-C illustrate partial, cross-sectional views of a memory array according to another example of multiple fin capacitors at process steps subsequent to the process step shown in FIGS. 14A-C.

FIG. 20 illustrates a partial, top view of selected metallization components in a memory array.

FIG. 21 illustrates a partial, isometric view of selected metallization components in a memory array.

### DETAILED DESCRIPTION

The example implementations described herein refer to the accompanying drawings. The same reference numerals in the various drawings may identify the same or similar features.

### Substantially Vertical Bitline.

In some instances, known two-dimensional (2D) memory architecture is adapted to three-dimensional (3D) memory architecture by stacking levels of 2D arrays. The 2D array levels are essentially the same as they would be if formed as only a 2D architecture, but the levels are electrically connected. That approach necessitates spacing between levels. Also, because of the level thickness, fewer levels can be stacked compared to the number of thinner levels that could be stacked, if they existed. Those restrictions reduce the potential density of stacked memory cells, that is, memory cells per unit area of substrate, even though the density would be greater than a 2D array. Also, difficulty can arise with forming electrical connections between levels when individual stacked levels are formed in separate process steps.

Some examples described herein provide a substantially vertical bitline along with a channel at an elevational level above and separated from the substrate and on a side of and electrically connected to the bitline. A memory cell including the bitline and the channel may thus be placed at any elevational level along the bitline. Some examples described herein allow simultaneously forming a plurality of such memory cells.

Therefore, some implementations described herein permit the placement of a memory cell, including multiple memory cells, along the substantially vertical bitline at any elevational level, including multiple elevational levels. Multiple memory cells along the bitline may form a column of memory cells. Additional columns of memory cells may be included to form a 3D memory array with cells vertically much closer in proximity compared to stacking levels of known 2D memory arrays. Since each memory cell in a column and in neighboring columns may be formed simultaneously, defects are reduced compared to making electrical connections between stacked levels of 2D arrays.

### Double-Bit Memory Cell.

In some instances, a memory cell referred to as a “double-bit memory cell” may include two storage nodes accessed via a bitline shared in common. A double-bit memory cell might be used to increase the density of storage nodes, that is, storage nodes per unit area of substrate. Theoretically, density increases because one bitline is used for two storage nodes, instead of two bitlines, making more space available for memory cells. However, decreasing the number of bitlines might not create more space if the size of capacitors necessary to obtain a desired minimum capacitance is instead the limiting factor. That is, the space needed to accommodate a minimum capacitor size could prevent adding more memory cells, even if they are double-bit memory cells.

Some examples described herein provide a first channel and a second channel both at a first elevational level above the substrate on opposing sides of and electrically connected to a bitline. A first capacitor is electrically connected to the first channel. A second capacitor is electrically connected to the second channel. A double-bit memory cell including the bitline may thus be placed at any elevational level along the bitline.

Therefore, some implementations described herein permit the placement of a double-bit memory cell, including multiple double-bit memory cells, along the bitline at any elevational level, including multiple elevational levels. Multiple double-bit memory cells along the bitline may form a column of double-bit memory cells. Forming the double-bit memory cells in columns thus relieves the constraint of accommodating a minimum capacitor size within the limited area available on a substrate. In one implementation, the bitline may be a substantially vertical bitline. In another implementation, the first and second capacitors may be at the first elevational level lateral from the respective first and second channels.

### Fin Capacitor.

In some instances, capacitance is increased by increasing the opposing surface area of capacitor electrodes in a memory cell. Often, a bottom electrode is formed on top of the transistors in an array of memory cells. The bottom electrode may include a vertical wall formed with an open top allowing placement of a top electrode within the space enclosed by the vertical wall. Compared to flat, opposing plates as capacitor electrodes, the vertical wall bottom electrode increases surface area, which increases capacitance. Known 2D memory arrays using such capacitors would thus increase in height. If adapted into 3D memory architecture by stacking levels of the 2D array, fewer levels can be stacked compared to the number of thinner levels that could be stacked, if they existed. That restriction reduces the potential density of stacked memory cells.

Some examples described herein provide a capacitor including a primary capacitor electrode electrically connected to the channel, the primary capacitor electrode forming one or more container structures that have an open side, instead of an open top. A secondary capacitor electrode extends to within the one or more container structures. The described arrangement may also be referred to as a “fin” capacitor.

Therefore, some implementations described herein permit the placement of primary capacitor electrodes as open-sided container structures at any elevational level, including multiple elevational levels. Multiple memory cells with such a primary capacitor electrode may form a column of memory cells. Forming the open-sided primary capacitor electrodes thus provides memory cells much closer in proximity compared to stacking levels of known 2D memory arrays with open-top capacitors.

### Higher Performing Materials.

In some instances, known 2D memory architecture relies on known processing techniques and might be constrained to use existing materials known for their suitability with such processes. Even if higher performing materials become available, they might not be suitable for the oft-used 2D architecture processing techniques.

Some examples described herein involve forming first and second layers of channel material at respective first and second increasing elevational levels above and separated from a substrate. Early process steps may deposit a simple stack of alternating layers of channel material and insulative material. The processing is thus suitable for incorporating multiple elevational levels of channel materials that exhibit increased electron mobility in comparison to known channel materials used in 2D memory arrays.

Therefore, some implementations described herein may deposit planar layers of channel materials with increased electron mobility without concern for deposition over difficult topographies. Also, the increased mobility permits using less volume of channel material, enabling higher memory cell density.

### FIGURES

As indicated above, the figures are provided merely as examples. Other examples are possible and may differ from what is described with regard to the figures.

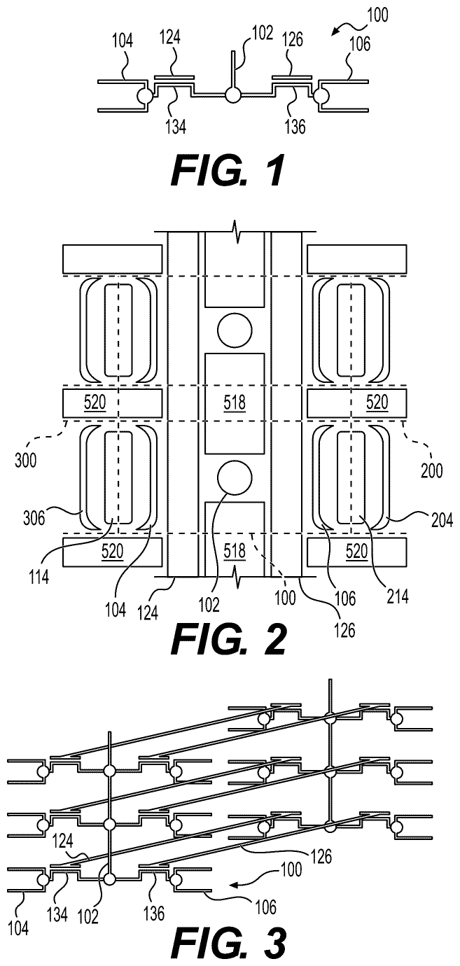

FIG. 1 is a conceptual schematic of a memory cell 100 including a bitline 102 electrically connected to a channel 134 and a channel 136, in turn electrically connected to a primary capacitor electrode 104 and a primary capacitor electrode 106, respectively. Memory cell 100 also includes a wordline 124 operationally associated with channel 134 and a wordline 126 operationally associated with channel 136. Memory cell 100 is a double-bit memory cell.

FIG. 2 is a conceptual, top view of selected components in a portion of a memory array including memory cell 100 shown in FIG. 1. Since FIG. 2 is a top view, it shows memory cell 100 repeated laterally (the upward and downward direction in FIG. 2) with wordlines 124, 126 extending laterally to neighboring memory cells. Primary capacitor electrode 104 shares a secondary capacitor electrode 114 with a primary capacitor electrode 306 of a neighboring memory cell 300. Likewise, primary capacitor electrode 106 shares a secondary capacitor electrode 214 with a primary capacitor electrode 204 of a neighboring memory cell 200. Channel isolation 518 and capacitor isolation 520 separate neighboring memory cells.

FIG. 3 is a conceptual, isometric view of the memory cell in FIG. 1 arranged in a memory array. Repeating, vertically arranged memory cells 100 appear along bitline 102 as a vertical bitline. FIG. 3 also shows wordlines 124, 126 extending laterally to a neighboring column of repeating, vertically arranged memory cells 100. Although FIG. 3 is only a conceptual view, components of memory cell 100 are arranged in FIG. 3 in like manner to the memory cells shown in FIGS. 15A-C and 19A-C. In both, bitline 102 is vertical with memory cells 100 arranged vertically along bitline 102 and wordlines 124, 126 extending laterally to neighboring columns of memory cells.

In the example of FIGS. 1-3, memory cell 100 is a double-bit memory cell. Accordingly, memory 100 includes two storage nodes as primary capacitor electrodes 104 and 106. Although the 3D memory architecture described herein increases memory cell density in part with double-bit memory cells, single-bit memory cells could be used in a similar architecture merely by providing memory cells on only one side of the bitline. The single-bit memory cells herein would also increase memory cell density.

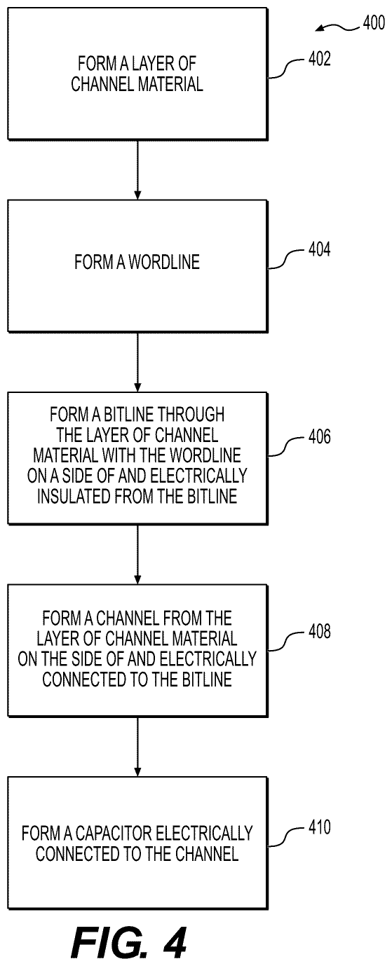

FIG. 4 is a flow diagram of a DRAM device forming method 400. A step 402 includes forming a layer of channel material at a first elevational level above and separated from a substrate. A step 404 includes forming a wordline at a second elevational level above and separated from the substrate. A step 406 includes forming a bitline through the layer of channel material. The bitline is substantially vertical with respect to the substrate along the bitline's longest dimension. The wordline is on a side of and electrically insulated from the bitline. A step 408 includes forming a channel from the layer of channel material. The channel is on the side of and electrically connected to the bitline. The wordline is elevationally above or below the channel. A step 410 includes forming a capacitor electrically connected to the channel. In method 400, a combination of the substantially vertical bitline, the channel, the capacitor, and the wordline provides at least a part of a memory cell.

As will be appreciated from the description below, method 400 may be used to form one or more additional memory cell of the same structure as the memory cell. The additional memory cell may be elevationally above or below the memory cell completed in step 410 with the respective channel of the additional memory cell electrically connected to the same bitline, thus providing a column of memory cells. As one example, the wordline and the additional wordline may be formed simultaneously in step 404. Similarly, as one example, the channel and the additional channel may be formed simultaneously in step 408. Further, as one example, the capacitor and the additional capacitor may be formed simultaneously in step 410.

Still further, as one example, the bitline may be a first bitline and the column of memory cells may be a first column of memory cells. Method 400 may be used to form a substantially vertical second bitline parallel to the first bitline. The first and second bitlines may be formed simultaneously in step 406. Simultaneous to forming the first column of memory cells, a second column of memory cells of the same structure as the first column may be formed, but with respective channels electrically connected to the second bitline. Wordlines of the first column that extend substantially laterally from the memory cells of the first column to provide wordlines in the second column may be formed in step 404, thus providing a substantially vertical, two-dimensional array of memory cells.

A structure described herein as “substantially vertical” is oriented in a substantially vertical direction with respect to a bulk substrate over which the structure is formed instead of in a lateral direction. For example, a bulk semiconductor wafer may define a lateral plane and the longest dimension of a bitline may be oriented substantially vertically with respect to the wafer plane. Within the meaning of “substantially” vertical, the bitline's longest dimension may be oriented perpendicular with respect to the bulk substrate, but may also deviate from a perpendicular direction by up to 45°.

Likewise, a structure described herein as “substantially lateral” is oriented in a substantially lateral direction with respect to the bulk substrate over which the structure is formed instead of in a vertical direction. For example, a bulk semiconductor wafer may define a lateral plane and the longest dimension of a wordline may be oriented substantially laterally with respect to the wafer plane. Within the meaning of “substantially” lateral, the wordline's longest dimension may be oriented parallel with respect to the bulk substrate, but may also deviate from a parallel direction by up to 45°.

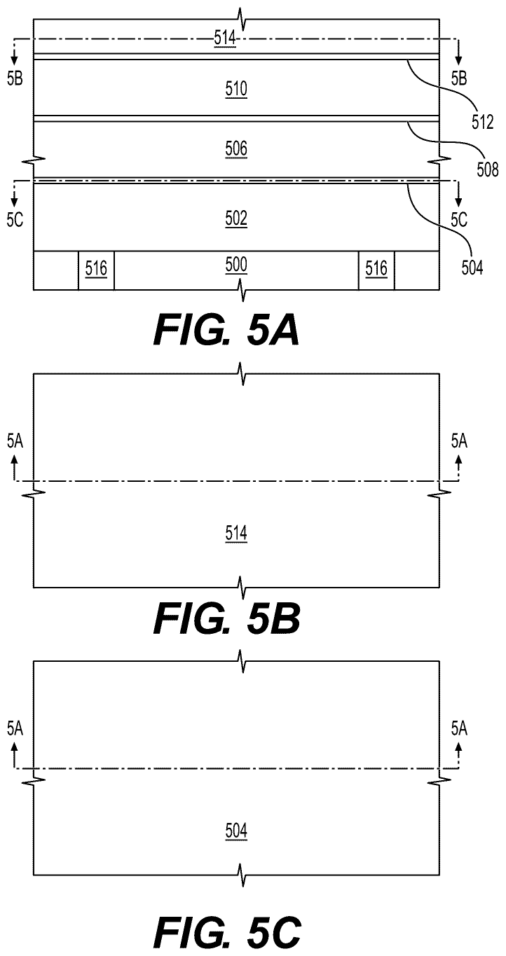

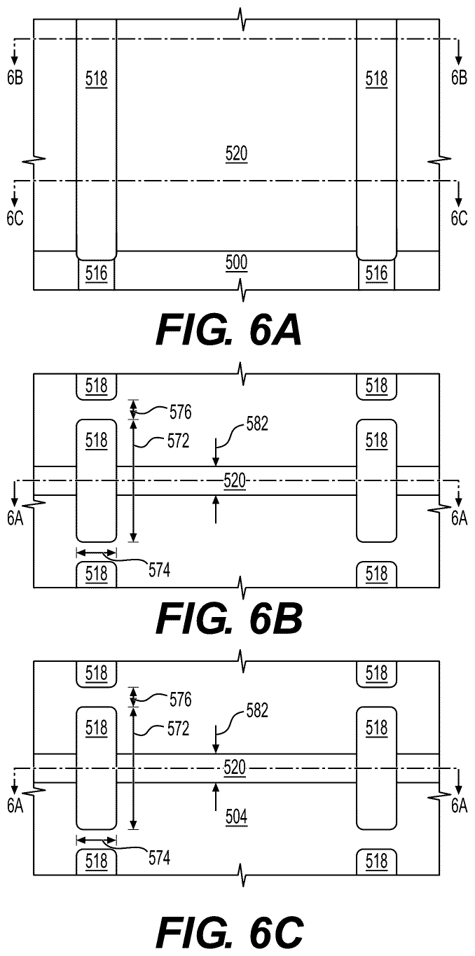

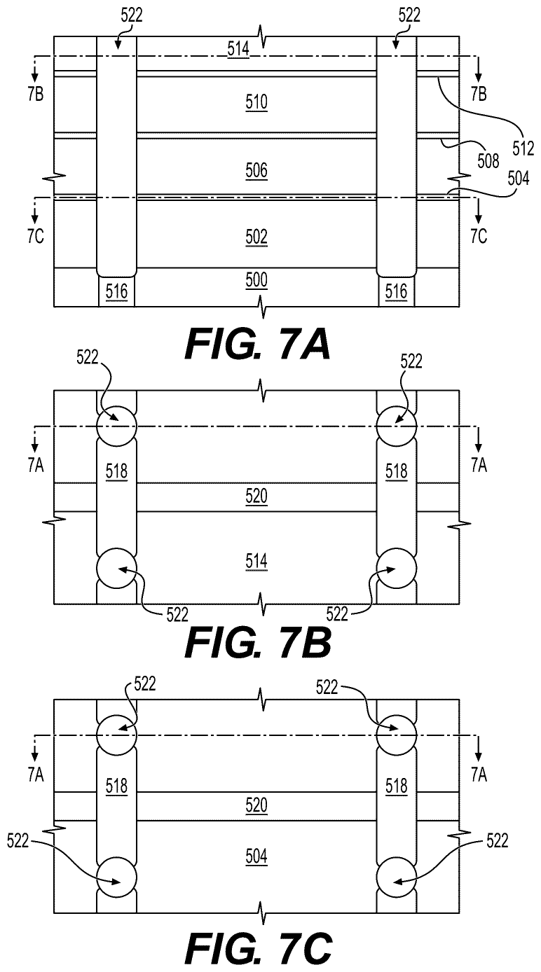

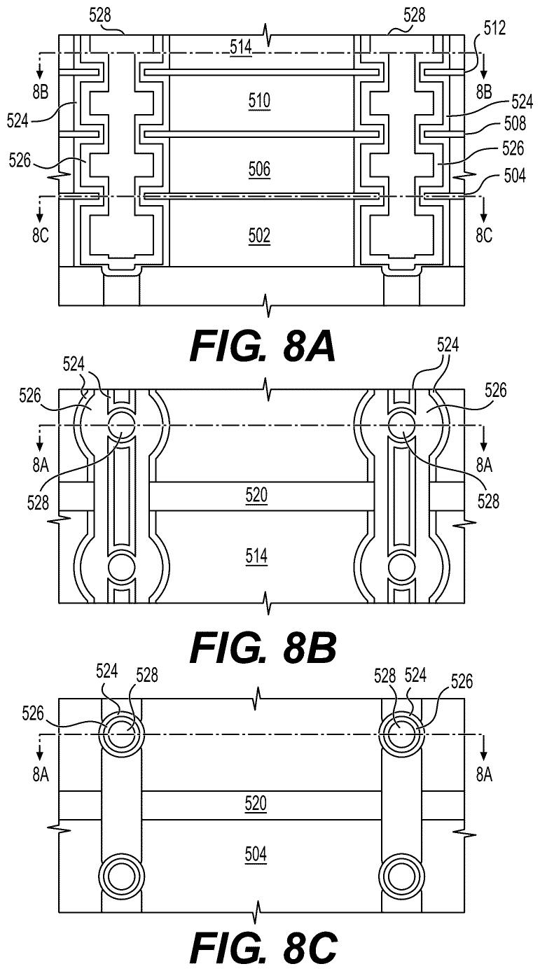

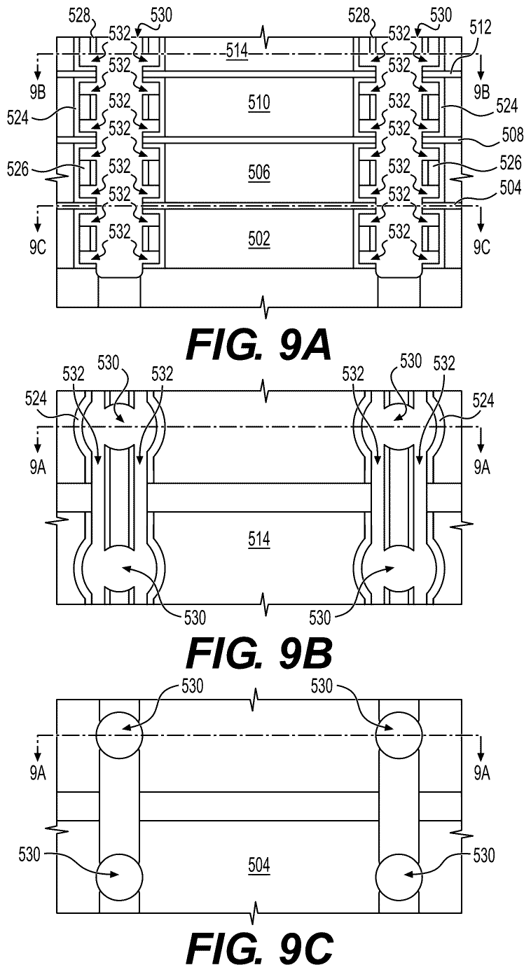

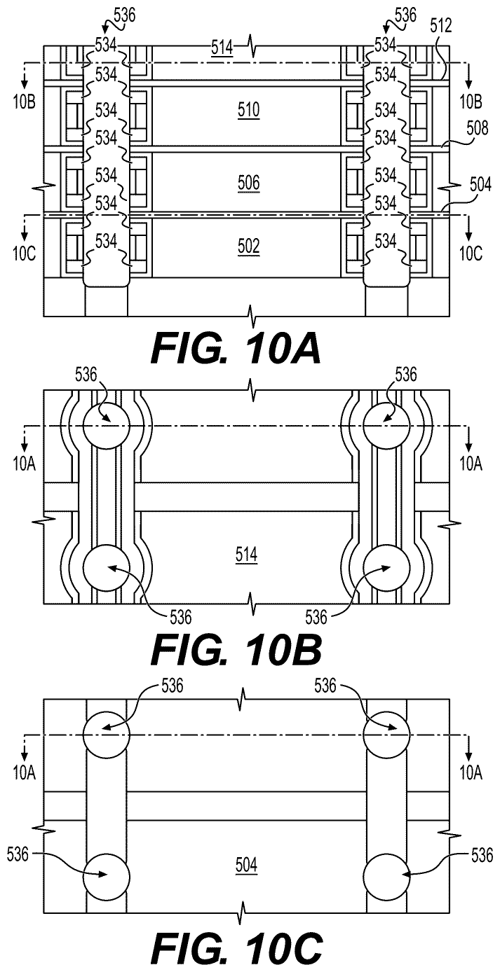

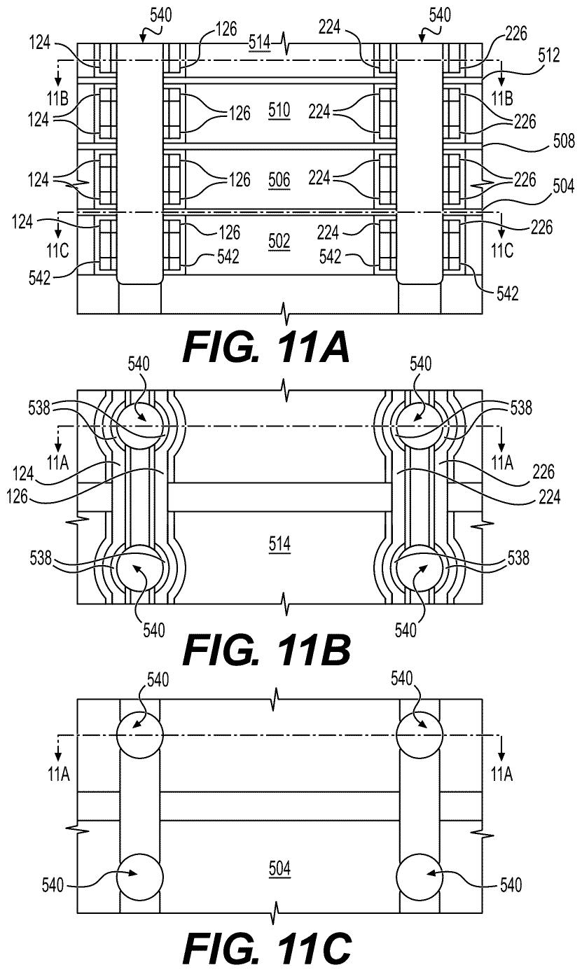

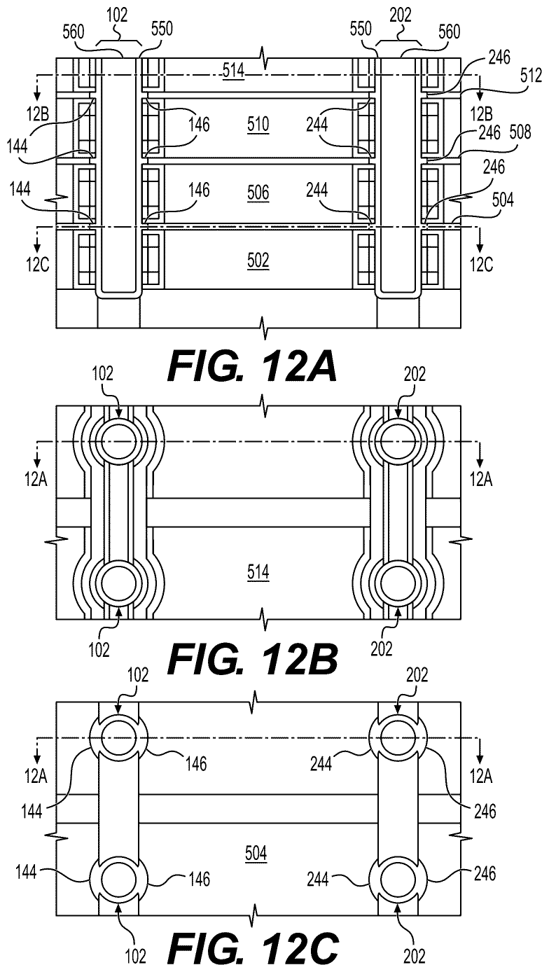

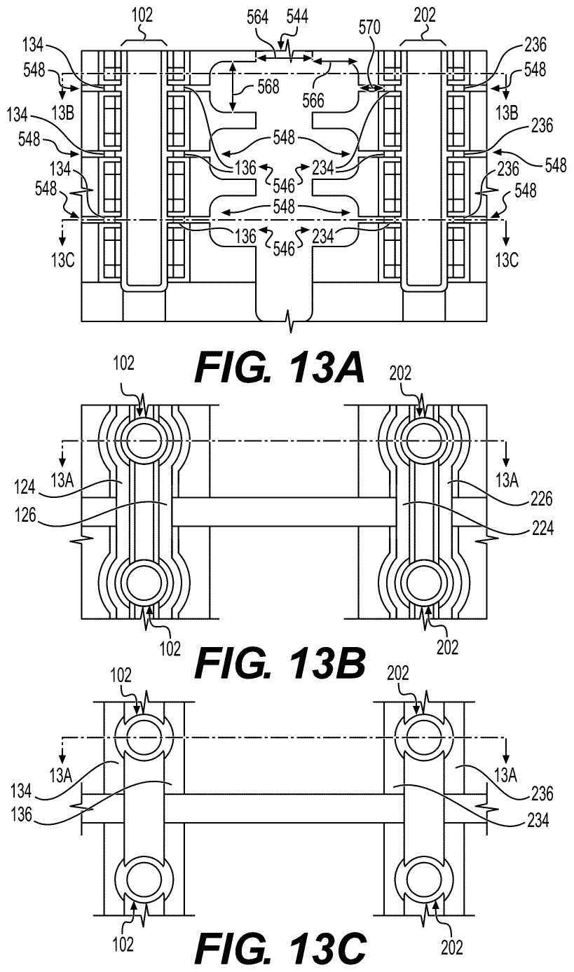

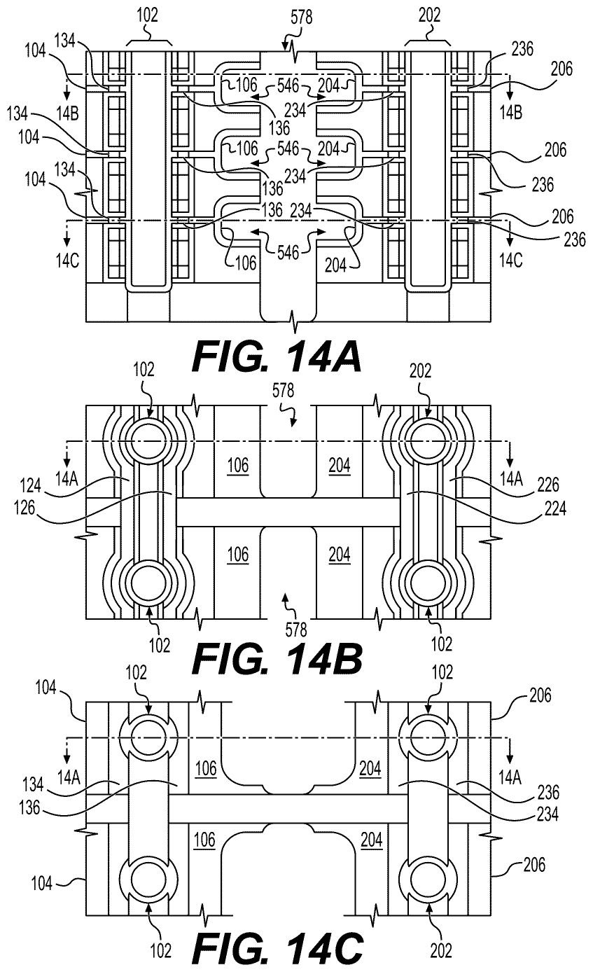

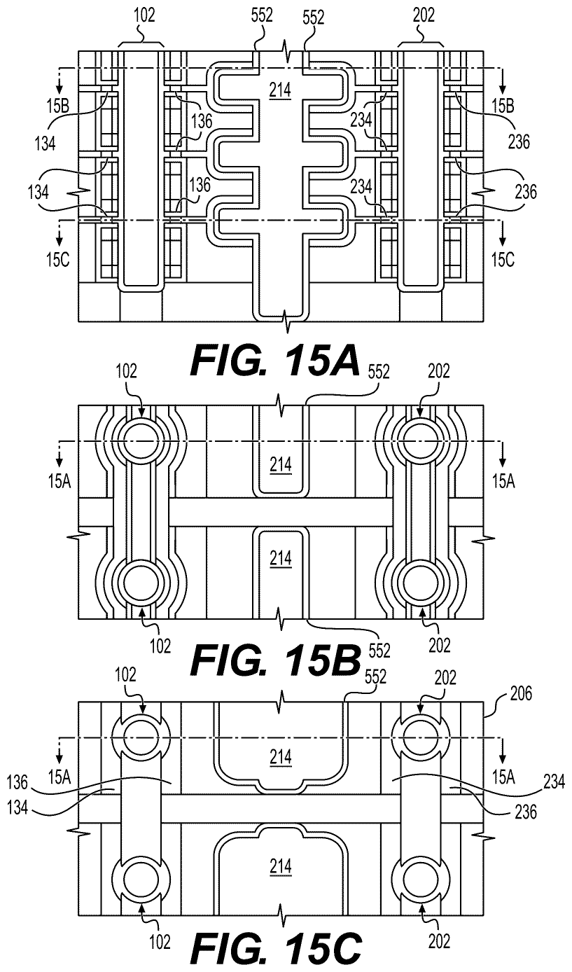

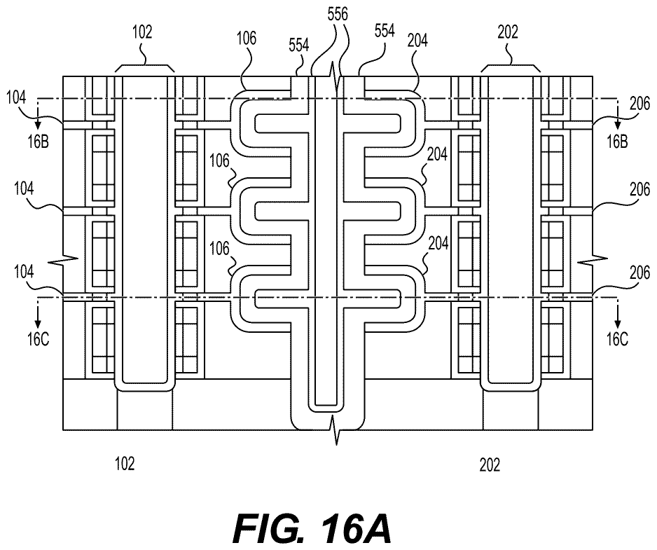

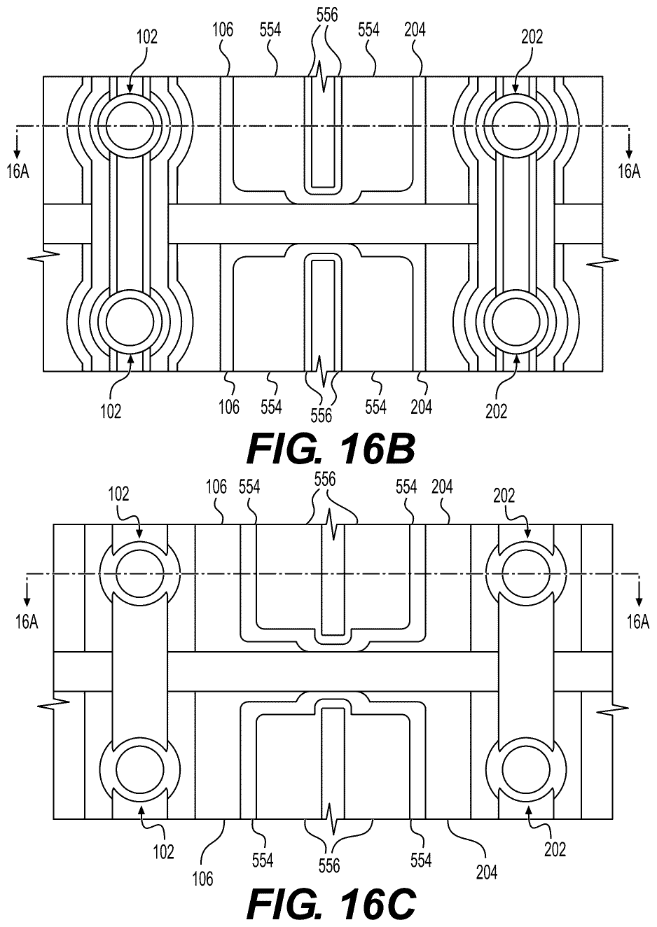

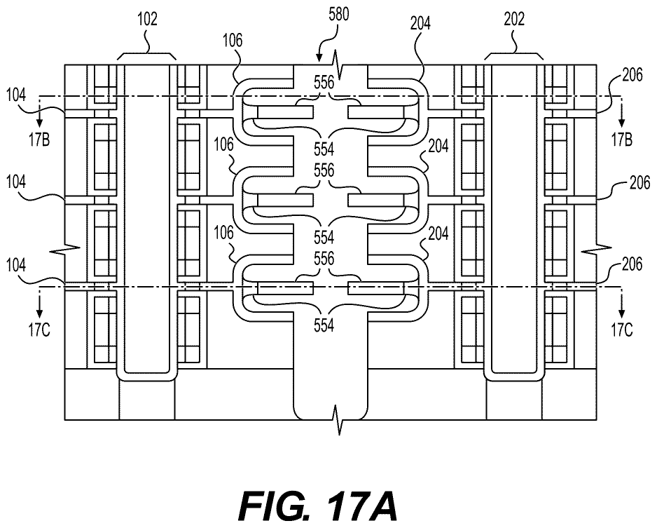

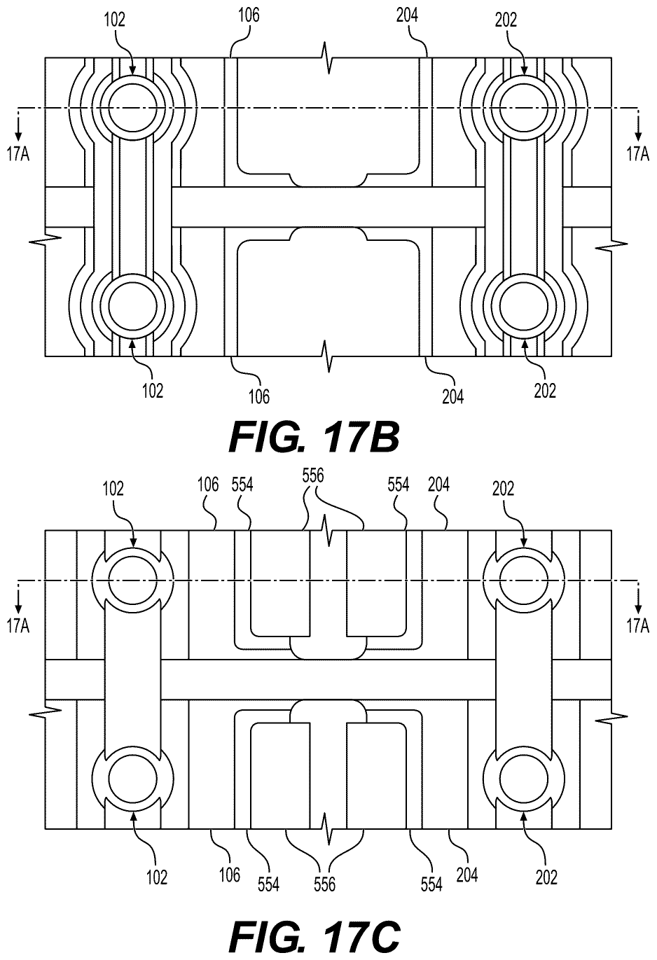

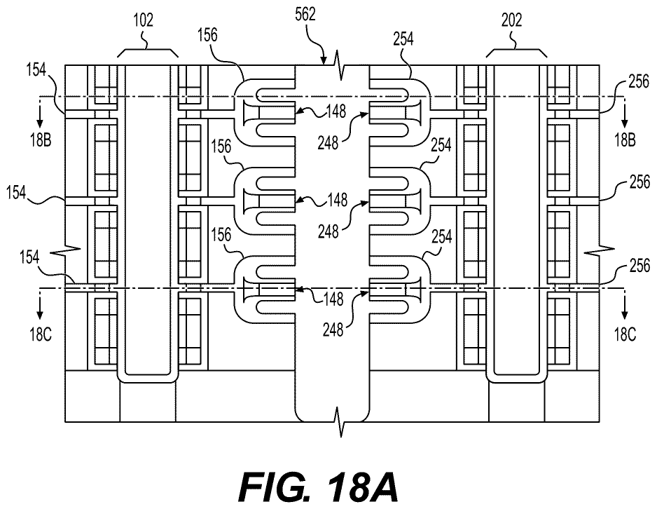

FIGS. 5A-C to 14A-C illustrate partial, cross-sectional views of a portion of a memory array at successive process steps. FIG. 15A-C illustrate partial, cross-sectional views of a memory array according to one example at a process step subsequent to the process step shown in FIGS. 14A-C. FIGS. 16A-C to 19A-C illustrate partial, cross-sectional views of a memory array according to another example at process steps subsequent to the process step shown in FIGS. 14A-C. Cross-section “A” in the figures is a side view. Cross-sections “B” and “C” are top views taken at different elevational levels above the substrate.

The figures are not drawn to scale and are instead conceptual and intended to explain the geometric relationships between components. The figures are also intended to show selected examples of successive process steps sufficient to yield the desired structures. Conceivably, other process steps could be used to yield the same structures or similar structures with the same functions described herein. Nevertheless, the process steps herein possess certain benefits, as described.

### Isolation Patterning Module.

FIGS. 5A-C and 6A-C show successive process steps in one example of an isolation patterning module. To obtain the structure shown in FIGS. 5A-C, shallow trench isolation openings are etched into a substrate 500 and filled with a shallow trench isolation 516. Known oxide-based isolation materials may be used, such as silicon dioxide. According to known techniques, when depositing materials in openings, excess material may be removed following deposition, as needed, by chemical-mechanical planarization (CMP) or other techniques. Alternating layers of an insulative material 502, a channel material 504, an insulative material 506, a channel material 508, an insulative material 510, a channel material 512, and an insulative material 514 are formed over substrate 500. As one example, three layers of channel material are shown in the figures. Additional layers may be included by repeating the alternating layers.

Possible compositions for the layers of channel material include single crystal silicon, polycrystalline silicon, silicon germanium, indium gallium zinc oxide (IGZO), etc. with or without dopants, such as, graphene, quantum dots, alkali metals, etc. The layer of channel material may include a single layer of a single composition or multiple sublayers of alternating or differing compositions. The resulting channel may have a high electron mobility of 50 to 300 centimeter²/Volt-second (cm²/V·s), such as 100 to 300 cm²/V·s. Possible deposition techniques include chemical vapor deposition (CVD), atomic layer deposition (ALD), epitaxial growth, spin coating, self-assembling monolayer (SAM), etc. Insulative material may include known compositions and deposition techniques, such as silicon dioxide deposited using tetraethyl orthosilicate (TEOS).

A very large variety of known etching tools, etchant compositions, and etching methods are available for controlling etch results in a known manner, including overall etch rate, etch selectivity (etch rate of one material compared to another), etch direction, and other results. Such etching technology is widely known and employed. By carefully choosing the materials to be etched, known etching technology may very often be used in combination with novel material selections to form novel structures, such as the structures described herein. Since the etching technology relied on is widely known and varied, specific etching tools, etchant compositions, and etching techniques are not described. Accordingly, though examples may be given of general types of etching that may be suitable, known technology enables forming the structures herein.

The structure shown in FIGS. 6A-C may be formed by etching openings for channel isolation through the layers of insulative material and channel material 514, 512, 510, 508, 506, 504, and 502 and slightly into shallow trench isolation 516 to be certain of complete isolation, followed by filling the openings with channel isolation 518. As one example, the blocks of channel isolation 518 shown in FIGS. 6B and C may have a lateral length 572 of 320 nanometers (nm) and a lateral width 574 of 100 nm. The blocks of channel isolation 518 may be separated from one another by a lateral length 576 of 60 nm. Known isolation material may be used for channel isolation 518, such as the same material used for shallow trench isolation 516.

Next, openings for capacitor isolation are etched through insulative material and channel material 514, 512, 510, 508, 506, 504, and 502 stopping on substrate 500, followed by filling the openings with capacitor isolation 520. Known nitride isolation materials, such as silicon nitride materials, may be used. Possible deposition techniques include CVD, low pressure chemical vapor deposition (LPCVD), etc. As one example, selection of lateral length 572 for channel isolation 518 may determine the dimension between blocks of capacitor isolation 520. As will be appreciated from the discussion herein, such selection may partially determine the capacitor size, influencing capacitor surface area and, thus, capacitance of the storage nodes. Also, such selection may define a channel width for a memory cell. As one example, the blocks of capacitor isolation 520 shown in FIGS. 6B and C may have a lateral width 582 of 50 nm. As a result, the dimension between blocks of capacitor isolation 520 may be 330 nm.

### Wordline and Bitline Formation Module.

FIGS. 7A-C to 12A-C show successive process steps in one example of a wordline and bitline formation module. To obtain the structure shown in FIGS. 7A-C, bitline openings 522 are formed at the gaps between channel isolation 518 through insulative material and channel material 514, 512, 510, 508, 506, 504, and 502 and slightly into shallow trench isolation 516.

Forming the structure shown in FIGS. 8A-C includes first recessing bitline openings 522 into insulative material 514, 510, 506, and 502 and through portions of channel isolation 520 exposed thereby. Potential recessing methods include wet etching, chemical dry etching, such as radical dry etching, atomic layer etching, etc. In addition to recessing beyond the diameter of bitline openings 522, the recessing opens pathways along both sides of channel isolation 518 between bitline openings 522. Ultimately, the pathways enable wordlines (discussed below) to extend laterally between memory cells.

The recessing leaves channel isolation 518 as a nearly freestanding structure. A freestanding structure could be susceptible to toppling during subsequent processing. Nevertheless, FIG. 8C shows that channel material 504 maintains contact with channel isolation 518. Likewise, though not shown in the figures, channel materials 508, 512 also maintain contact with channel isolation 518. Channel materials 504, 508, 512 thus prop up channel isolation 518 during subsequent processing.

After recessing, gate dielectric material is conformally deposited in the openings to provide a layer of gate dielectric material 524 shown in FIGS. 8A-C. Known gate dielectric materials, such as silicon dioxide, hafnium oxide, zirconium oxide, combinations thereof, etc. may be used.

Next, a layer of sacrificial liner 526 is conformally deposited over gate dielectric material 524. Known sacrificial liner materials, such as silicon nitride, polycrystalline silicon, silicon germanium, other silicon systems, etc., may be used. The selected sacrificial liner materials may be removed by a selective etch without removing oxide-based materials, such as silicon dioxide. The remaining openings are filled with an isolation material 528, such as the same material used for shallow trench isolation 516.

With the additional materials deposited in the recesses around and filling bitline openings 522, they are reopened forming bitline openings 530 through isolation material 528, sacrificial liner 526, and gate dielectric material 524 again in the shape of bitline openings 522. Bitline openings 530 have the final hole size to persist for the subsequently formed bitlines. As one example, bitline openings 530 (and the subsequent bitlines) may have a 100 nm diameter. As one example, an anisotropic dry etch may be suitable.

To form the structure shown in FIGS. 9A-C, wordline openings 532 are formed by etching portions of sacrificial liner 526 exposed through bitline openings 530. Potential techniques for recessing sacrificial liner 526 include wet etching, chemical dry etching, such as radical dry etching, and atomic layer etching, etc.

With wordline openings 532 formed, a conformal layer of wordline material 534 is formed in wordline openings 532 and partially fills bitline openings 530. Wordline material 534 may include a single material or multiple sublayers of different materials. For example, a wordline barrier deposited first may include titanium, titanium nitride, titanium silicon nitride, tantalum, tantalum nitride, tantalum silicon nitride, etc. After forming the wordline barrier, a wordline fill may be deposited containing tungsten, ruthenium, cobalt, molybdenum, etc. Often, no wordline barrier is needed for ruthenium. Following deposition of the layer of wordline material 534, bitline openings 536 are opened by etching excess wordline material 534 to form the structure shown in FIGS. 10A-C.

Since FIGS. 10A-C show wordline material 534 bordering bitline openings 536, a bitline formed in bitline openings 536 would contact and short circuit with wordline material 534. Accordingly, a controlled recess of the portions of wordline material 534 exposed through bitline openings 536 is performed to etch back a portion of wordline material 534 to form wordlines 124, 126, 224, and 226 shown in FIGS. 11A-C. Such wordlines may be formed simultaneously. As one example, the recess may be about 10 nm to reduce leakage between the wordline and the bitline. Potential recessing methods include wet etching, chemical dry etching, such as radical dry etching, atomic layer etching, etc.

A conformal layer of insulative material is deposited and etched to form bitline openings 540, leaving in place bitline insulators 538, as shown in FIGS. 11A-C. Known insulative material may be used for bitline insulators 538, such as the same material used for shallow trench isolation 516. Notably, FIGS. 11A-C also show dummy wordlines 542 at the bottom of bitline openings 540. During the controlled recess of wordline material 534 shown in FIGS. 10A-C, the portions of wordline material 532 that form dummy wordlines 542 may act as a control for correctly timing the controlled recess.

FIGS. 11A-C show wordlines 124, 126, 224, 226 both above and below individual layers of channel material 504, 508, 512 and separated therefrom by gate dielectric material 524. Whether above or below the channel, such wordlines may be in operable juxtaposition with the channels to be formed. Either the upper or the lower wordline may be used for a memory operation since one is redundant. That is, the upper and lower wordlines are independent and not shorted to each other. In summary, two wordlines share a common channel. In such manner, either may be selected for use if the other becomes inoperable and the redundancy of word lines reduces the potential effect of defects.

Although bitlines could be formed at this point in bitline openings 540 to interconnect with layers of channel material 504, 508, 512, doing so would leave a portion of channel materials 504, 508, 512 “ungated.” That is, wordlines 124, 126, 224, 226 would not overlap a portion of channel materials 504, 508, 512 that exist along a conductive path between the channel to be formed and the bitline to be formed. By first recessing channel material 504, 508, 512 exposed through bitline openings 540, the ungated channel material is removed. Potential recessing methods include wet etching, chemical dry etching, such as radical dry etching, atomic layer etching, etc.

After the channel material recessing, bitlines 102 and 202 are formed as shown in FIGS. 12A-C. Such bitlines may be formed simultaneously. As one example, bitlines 102 and 202 may be substantially vertical with respect to the substrate along the bitline's longest dimension. As shown, bitlines 102 and 202 are vertical.

As one example, bitlines 102 and 202 formed in bitline openings 540 may include a bitline barrier 550 that lines the wall of bitline openings 540 and fills the recesses in channel materials 504, 508, 512. The remainder of bitlines 102 and 202 may be formed with bitline fill 560. Bitline barrier 550 may contain titanium, titanium nitride, titanium silicon nitride, tantalum, tantalum nitride, tantalum silicon nitride, etc. Bitline fill 560 may contain tungsten, ruthenium, cobalt, molybdenum, etc.

As a result of the channel material recessing, bitline barrier 550 fills the recess and provides bitline arms 144, 146 as a part of bitline 102 and bitline arms 244, 246 as a part of bitline 202. FIGS. 12A-C show bitlines 102, 202 as including bitline barrier 550 and bitline fill 560. In appropriate circumstances, bitlines 102 and 202 might be formed from a single material instead of from a barrier material and a fill material.

### Capacitor Formation Module.

FIGS. 13A-C to 19A-C show successive process steps in one example of a capacitor formation module. The structures shown in FIGS. 13A-C are formed in four etching steps. First, a main slot (not shown) is etched through layers of insulative material and channel material 514, 512, 510, 508, 506, 504, 502, and into substrate 500. Second, with the main slot exposing layers of channel material 512, 508, 504, the layers of channel material are etched back to a desired capacitor depth. The etching forms side slots (not shown) opening into the main slot.

Third, with the channel material recessed, insulative materials 514, 510, 506, 502 are recessed to widen the main slot to become main slot 544 and to form lateral capacitor recesses 546 opening into main slot 544. Capacitor recesses 546 are etched back laterally to the capacitor depth. The capacitor depth is selected by the extent of recessing the layers of channel material 512, 508, 504. The nature of this recess produces a curved profile where lateral walls meet vertical walls inside capacitor recesses 546. The curved profile reduces leakage currents.

Fourth, the layers of channel material 504, 508, 512 are further recessed to remove ungated channel material. This second etch back of channel material thus forms channels 134, 136, 234, 236 and side slots 548. Comparing the relative positions of wordlines 124, 126, 224, 226 and channels 134, 136, 234, 236 in FIGS. 13A-C, it will be appreciated that they overlap with gate dielectric 524 between them and they are in operable juxtaposition. That is, when a wordline energizes, a conductive path between the capacitor and the bitline activates in the channel.

Dimensions of the channel define a channel aspect ratio (width:length) (W/L). The channel aspect ratio is linked to transconductance and current capability, together with the multiplicity factor (M). A higher W/L increases current gain and yields a higher current for a given gate voltage (V_{g}). Wordlines 124, 126, 224, 226 noticeably curve around bitlines 102, 202. Judging from the overlap with channels 134, 136, 234, 236, the gated portion of the channels likewise curves around bitlines 102, 202. Due to the channel curvature, channel width (W) is greater than the dimension in each memory cell between blocks of capacitor isolation 520 that confine the channels. As one example, W may be greater than 60 nm, such as greater than 150 nm, including greater than 300 nm.

Channel length (L) is the dimension along the conductive path between the capacitor and the bitline. As one example, L may be about 10 nm. For the geometry of FIGS. 13A-C, the channel aspect ratio W/L may be greater than 6, such as greater than 15, including greater than 30. The geometry and channel curvature thus increase channel current compared to channels with a lower W/L.

After the fourth process step, the recesses formed may have specified dimensions according to one example. Main slot 544 may have a lateral width 564 of 200 nm shown in FIGS. 13A-C. Capacitor recess 546 may have a lateral width 566 determined by the selected capacitor depth of 100 nm. Capacitor recess 546 may have a vertical height 568 of 120 nm. Side slot 548 may have a lateral width 570 of 60 nm. Consequently, the four process steps provide capacitor recesses 546 that open laterally into main slot 544. Likewise, side slots 548 open laterally into capacitor recesses 546. Potential recessing methods for the four steps include wet etching, chemical dry etching, such as radical dry etching, atomic layer etching, etc., depending on the specific materials to be etched and the desired shape of the resulting structure.

FIGS. 14A-C show that primary capacitor electrode material is conformally deposited into main slot 544, capacitor recesses 546, and side slots 548. The primary capacitor electrode material may include titanium, titanium nitride, titanium silicon nitride, etc. Thereafter, excess electrode material is etched forming main slot 578 and separating primary capacitor electrodes 106, 204. Primary capacitor electrodes 104, 106, 204, 206 formed in side slots 548 and capacitor recesses 546 are electrically connected to respective channels 134, 136, 234, 236. Such primary capacitor electrodes may be formed simultaneously. As one example, primary capacitor electrodes 104, 106, 204, 206 may extend the full dimension between blocks of capacitor isolation 520, as shown in FIGS. 14B and 14C.

Primary capacitor electrodes 106, 204 form container structures that open laterally into main slot 578. Capacitor recesses 546 and container structures for primary capacitor electrodes 104, 206 are not shown in FIGS. 14A-C, but are nonetheless formed by the described method and according to the architecture shown in FIG. 2.

With the completion of primary capacitor electrodes 104, 106, 204, 206, the formation of memory cells diverges into two paths with one option forming single fin capacitors and another option forming multiple fin capacitors. A single fin increases the opposing surface area of capacitor electrodes, which increases capacitance, in a memory cell compared to flat, opposing plates as capacitor electrodes. With multiple fins, the opposing surface area, and thus capacitance, may be further increased.

FIGS. 15A-C show the single fin option. A capacitor dielectric 552 is conformally deposited in main slot 578 and the container structures formed by primary capacitor electrodes 106, 204 (and the container structures formed by primary capacitor electrodes 104, 206, though not shown). The capacitor dielectric material may include hafnium oxide, zirconium oxide, lanthanum oxide, titanium oxide, combinations thereof, etc. Next, the remainder of main slot 578 and capacitor recesses 546 is filled with a secondary capacitor electrode 214. As an example, secondary capacitor electrode 214 may contain titanium nitride or tungsten. As a result, secondary capacitor electrode 214 provides a single electrode shared in common among opposing individual capacitors. Consequently, the capacitors electrically connected to channels 134, 136, 234, 236 may be formed simultaneously.

It will be appreciated from FIGS. 15A-C that wordlines 124, 126 are associated with a vertical, 2D array of double-bit memory cells with bitlines 102. Also, wordlines 224, 226 are associated with a vertical, 2D array of double-bit memory cells with bitlines 202. As a result, FIGS. 15A-C show a first vertical, 2D array of memory cells and a second vertical, 2D array of memory cells parallel to each other. The parallel 2D arrays provide a 3D array of memory cells.

As another option, multiple fin capacitors may be formed. FIGS. 16A-C show conformal deposition of spacer material 554 in main slot 578 and the container structures formed by primary capacitor electrodes 106, 204. As one example, spacer material 554 may be conformally deposited to a thickness of 40 nm. With the dimensions given in the discussion above regarding FIGS. 13A-C, such a thickness for spacer material 554 leaves an opening remaining in main slot 578 with a lateral width of 120 nm. An opening with a vertical height of 20 nm remains within the container structure of primary capacitor electrodes 106, 204. Spacer material 554 may include silicon oxide-based insulative material, such as silicon dioxide. Spacer material 554 may be deposited using ALD.

Insulative material 556 is conformally deposited in the remaining opening of the container structures defined by primary capacitor electrodes 106, 204 and partially fills the remainder of main slot 578. Insulative material 556 may include nitride-based insulative material, such as silicon nitride. Insulative material 556 may be deposited using ALD.

The structure shown in FIGS. 17A-C are formed by first removing the vertical component of insulative material 556 to expose portions of spacer material 554. Then, spacer material 554 is etched to leave the portions shown in FIGS. 17A-C with lateral stacks of spacer material 554 and insulative material 556. The lateral stacks are within the container structures provided by primary capacitor electrodes 106, 204 and extending partially into main slot 580. Potential spacer etching methods include controlled wet etching, chemical dry etching, such as radical dry etching, etc. to remove spacer material 554 without removing remaining insulative material 556. Such methods may leave curved corners for subsequently deposited electrode materials to reduce leakage currents caused by sharp corners.

Additional primary capacitor electrode material may then be conformally deposited. The additional primary capacitor electrode material and a portion of the remaining insulative material 556 may then be etched to form main slot 562, capacitor dividers 148 and 248, and primary capacitor electrodes 154, 156, 254, and 256 in FIGS. 18A-C. Such primary capacitor electrodes may be formed simultaneously. Potential etching methods include anisotropic dry etching, etc. Capacitor dividers 148, 248 are within the container structures formed by primary capacitor electrodes 106, 204 in FIGS. 14A-C (and the container structures formed by primary capacitor electrodes 104, 206, though not shown), thus dividing the container structures. Accordingly, primary capacitor electrodes 156, 254 in FIGS. 18A-C in turn each form multiple container structures that open laterally into main slot 562.

The described method divides each container formed by primary capacitor electrodes 104, 106, 204, 206 into two containers using capacitor dividers 148, 248. The two containers permit forming a two-fin capacitor and increasing the opposing surface area of the capacitor electrode, which increases capacitance, compared to a single-fin capacitor. After dividing the containers formed by primary capacitor electrodes 104, 106, 204, 206, the method may be adapted to divide the containers again and then to form a primary capacitor electrode defining four containers. Similarly, six, eight, etc. containers may be formed in multiples of two. Accordingly, four-fin, six-fin, eight-fin, etc. capacitors may be formed.

For example, after forming the structure shown in FIG. 17A, the excess insulative material extending into main slot 580 may be etched back to form capacitor dividers 148, 248 prior to depositing additional primary capacitor electrode material. Then, the process of depositing and etching spacer material 554 and insulative material 556 shown in FIGS. 16A-C and 17A-C may be repeated, adding two more dividers to the containers formed by primary capacitor electrodes 104, 106, 204, 206. Additional primary capacitor electrode material may be deposited over the resulting structure and etched back, as shown in FIGS. 18A-C for a two-fin capacitor, to produce a primary capacitor electrode forming four containers. Subsequent formation of capacitor dielectric and a secondary capacitor electrode forms a four-fin capacitor.

The vertical spacing between layers of channel material influences the ability to form capacitors with more than two-fins since that determines the vertical height 568, shown in FIG. 13A, available for capacitor recesses 546. The vertical channel spacing for FIG. 13A may be from 150 to 300 nm. Channel spacing may be increased accordingly to accommodate more than two-fins.

The structures of FIGS. 19A-C are formed by first conformally depositing a capacitor dielectric 558 within main slot 562 and the multiple container structures provided by primary capacitor electrodes 154, 156, 254, 256. Next, a secondary capacitor electrode 264 is conformally deposited within the remainder of main slot 562 and the multiple container structures of primary capacitor electrodes 154, 156, 254, 256. Accordingly, secondary capacitor electrode 264 provides a single secondary capacitor electrode shared in common among opposing individual capacitors. The capacitors electrically connected to channels 134, 136, 234, 236 may be formed simultaneously. The capacitors may exhibit a capacitance of 1 to 100 femtoFarads (fF), such as 10 to 50 fF, including 30 fF. With the material compositions described herein, the dimensions shown in FIG. 13A, and the two-fin design in FIGS. 19A-C, increased capacitance levels are possible even with the increased memory cell density afforded by implementations described herein.

It will be appreciated from FIGS. 19A-C that wordlines 124, 126 are associated with a vertical, 2D array of double-bit memory cells with bitlines 102. Also, wordlines 224, 226 are associated with a vertical, 2D array of double-bit memory cells with bitlines 202. As a result, FIGS. 19A-C show a first vertical, 2D array of memory cells and a second vertical, 2D array of memory cells parallel to each other. The parallel 2D arrays provide a 3D array of memory cells.

### Contact Formation Module.

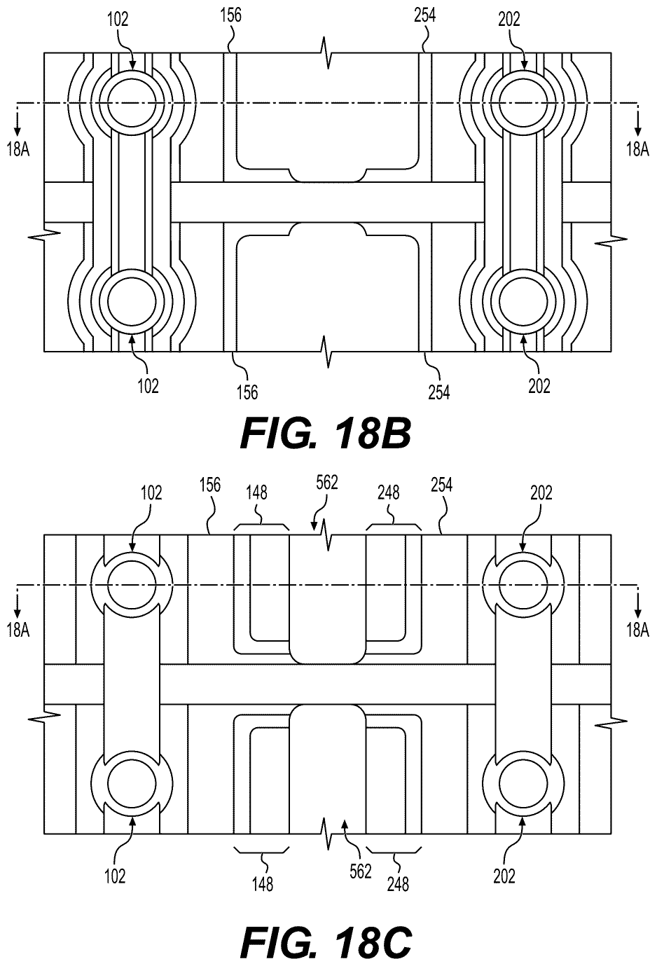

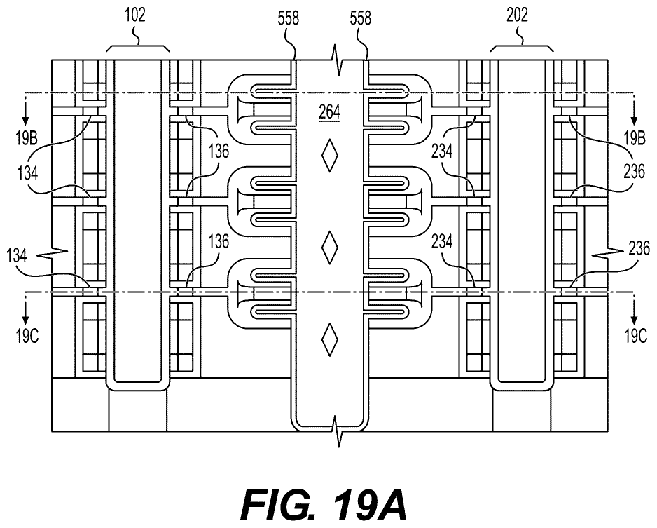

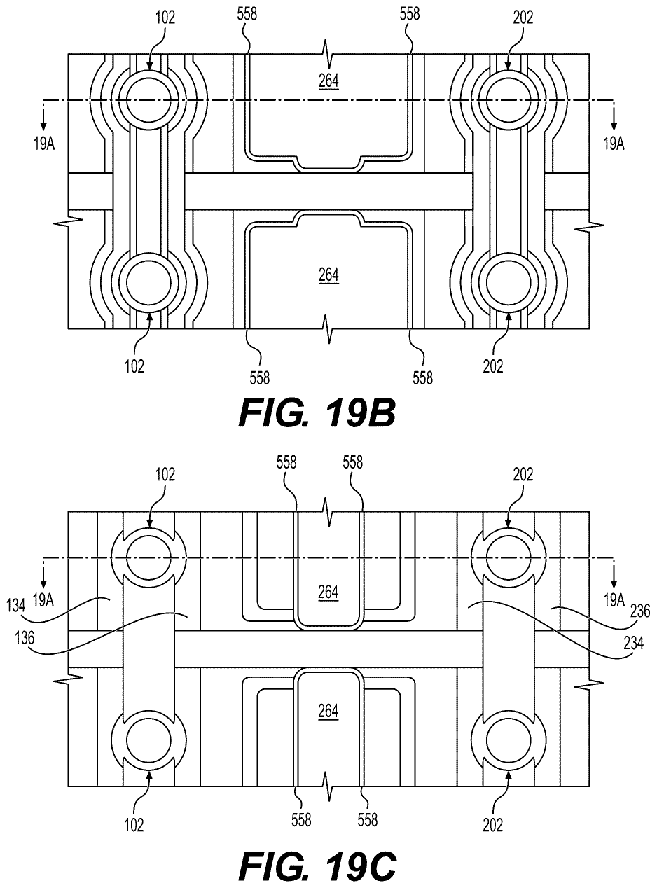

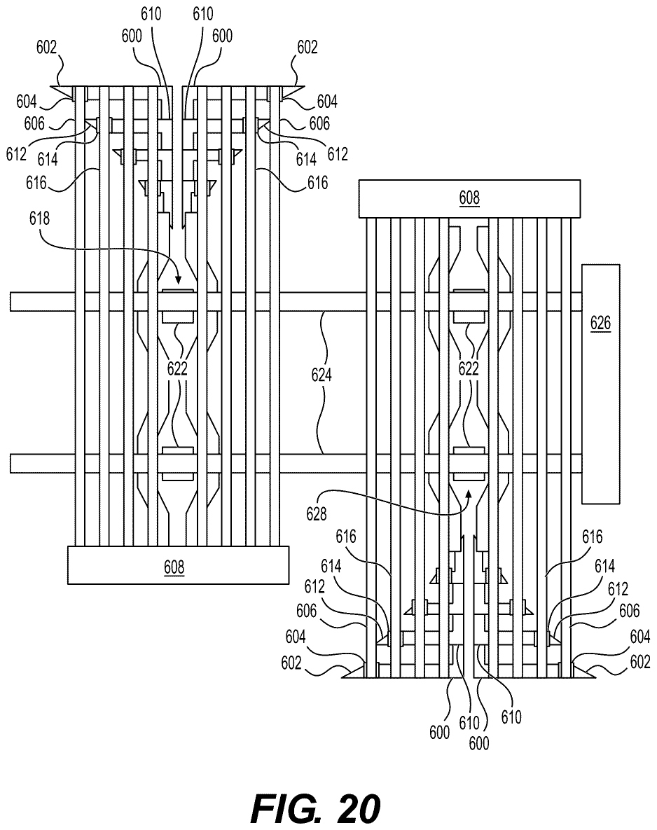

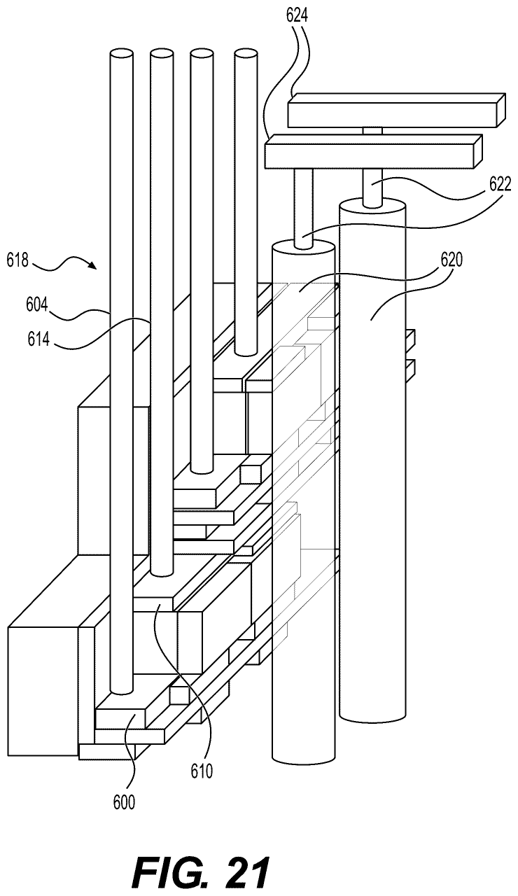

FIGS. 20 and 21 show the device resulting from successive process steps in one example of a contact formation module. FIG. 20 illustrates a partial, top view of selected metallization components at multiple elevational levels in a memory array. Wordlines 600 appear at the lowest elevational level shown and extend the furthest along their lengths to their ends. Wordlines 610 are elevationally higher and do not extend as far along their lengths to their ends in comparison to wordlines 600.

Laterally transverse wordline branches 602 extend at the ends of wordlines 600 to terminate at wordline contact pads (not shown). Wordline branches 602 are at the same elevational level as wordlines 600. Wordline branches 602 are electrically connected to separate, vertical wordline contacts 604 in turn electrically connected to separate, lateral top metal lines 606. Top metal lines 606 are at the highest elevational level shown in FIG. 20. Wordline contacts 604 extend between the highest elevational level of top metal lines 606 to electrically connect wordline branches 602 at the lowest elevational level.

Laterally transverse wordline branches 612 extend at the ends of wordlines 610 to terminate at wordline contact pads (not shown). Wordline branches 612 are at the same elevational level as wordlines 610. Wordline branches 612 are electrically connected to separate, vertical wordline contacts 614 in turn electrically connected to separate, lateral top metal lines 616. Top metal lines 616 are at the same elevational level as top metal lines 606. Wordline contacts 614 extend from the elevational level of top metal lines 616 to the lower elevational level of wordline branches 612, which are at a higher elevational level in comparison to wordline branches 602.

FIG. 20 shows additional wordlines that are at higher elevational levels in comparison to wordlines 602, 610. Their higher elevational level is readily apparent since all of the wordlines in FIG. 20 are vertical staggered. In vertical staggering, elevationally lower wordlines extend further along lengths of the wordlines to their ends. Vertical staggering creates a “staircase” formation from elevationally lower to elevationally higher wordline ends. Accordingly, the shorter wordlines are at higher elevational levels. Elevational levels of wordline branches are the same as their respective wordlines.

Also, wordline branches are laterally staggered in that the wordline branches are the longest for the furthest extending wordlines, creating a “tree” formation. Accordingly, the longest wordlines, that is, the wordlines at the lowest elevational level, have wordline branches that are the longest. Wordlines of the memory array in FIG. 20 are vertically arranged. Even so, the described combination of a staircase formation and a tree formation allow connection of top metal lines to wordlines without overlapping or forming top metal lines at different elevational levels. Top metal lines 606, 616 and other top metal lines in FIG. 20 are electrically connected to wordline decoders 608, which may be constructed and operated according to known technology.

The memory array of FIG. 20 includes bitlines (not shown), such as bitlines 102, 202 shown in FIGS. 15A-C and 19A-C. Bitline contacts 622 are electrically connected to the bitlines and extend upward to electrically connect with top metal lines 624. Top metal lines 624 are in turn, electrically connected to a sense amplifier 626, which may be constructed and operated according to known technology. Top metal lines 624 connected to bitline contacts 622 are at a lower elevational level in comparison to top metal lines 606, 616 connected to wordline contacts 604, 614, respectively.

It will be appreciated from the description herein that wordlines 600, 610 are associated with a vertical, 2D array of memory cells with bitlines underlying bitline contacts 622. As a result, FIG. 20 shows a first vertical, 2D array 618 of memory cells and a second vertical, 2D array 628 of memory cells parallel to each other. The parallel 2D arrays 618, 628 provide a 3D array of memory cells. As a result, sense amplifier 626 is electrically connected to both 2D arrays 618, 628.

FIG. 21 illustrates a partial, isometric view of selected metallization components in a memory array. The portion of a vertical, 2D array in FIG. 21 shows the staircase concept. For simplicity, wordline branches are not shown in FIG. 21. That is, the structure in FIG. 21 is vertically staggered, but not laterally staggered. Top metal lines 606 and 616 are not shown in FIG. 21, also for simplicity. Wordline contacts 604 and 614 may be electrically connected to respective wordlines without relying on wordline branches. However, top metal lines 624 are electrically connected to bitline contacts 622 in turn electrically connected to bitlines 620.

Top metal lines 606, 616 may include a titanium nitride barrier, a titanium layer, and an aluminum copper layer. Other known compositions are conceivable. Wordline contacts 604, 614 electrically connected to top metal lines 606, 616 may include a titanium nitride barrier and tungsten fill. Other known compositions are conceivable. Top metal lines 624 may include titanium nitride or a tantalum nitride barrier with copper fill. Other known compositions are conceivable. Bitline contacts 622 electrically connected to top metal lines 624 may include a titanium nitride barrier and tungsten fill. Other known compositions are conceivable.

### Devices and Methods.

The discoveries described herein identify a number of solutions that may be implemented in devices and methods also described herein. Multiple solutions may be combined for implementation, enabling still further devices and methods. The inventors expressly contemplate that the various options described herein for individual devices and methods are not intended to be so limited except where incompatible with other devices and methods. The features and benefits of individual devices herein may also be used in combination with methods and other devices described herein even though not specifically indicated elsewhere. Similarly, the features and benefits of individual methods herein may also be used in combination with devices and other methods described herein even though not specifically indicated elsewhere.

Device A is a DRAM device including a bitline that is substantially vertical with respect to a substrate along the bitline's longest dimension. A channel is at a first elevational level above and separated from the substrate and is on a side of and electrically connected to the bitline. A capacitor is electrically connected to the channel. A wordline is at a second elevational level above and separated from the substrate on the side of and electrically insulated from the bitline, the wordline being elevationally either above or below the channel. A combination of the substantially vertical bitline, the channel, the capacitor, and the wordline provide at least a part of a memory cell.

Additional features may be implemented in Device A. By way of example, the channel has a length along a conductive path within the channel between the capacitor and the bitline when the wordline is activated and the channel has a width transverse to the channel length. A channel aspect ratio of the channel width to the channel length may be greater than 6.

The capacitor may be at the first elevational level lateral from the channel. In such case, the capacitor may include a primary capacitor electrode electrically connected to the channel, the primary capacitor electrode forming one or more container structures that have an open side. A secondary capacitor electrode may extend to within the one or more container structures. A capacitor dielectric is between the primary and secondary capacitor electrodes.

A redundant wordline may be at a third elevational level above and separated from the substrate on the side of and electrically insulated from the bitline. The redundant wordline may be opposite the wordline with the channel between them.

Device A may include another channel at the first elevational level and electrically connected to the bitline, another capacitor electrically connected to the other channel, and another wordline at the second elevational level and electrically insulated from the bitline. The other wordline may be elevationally either above or below the other channel. A combination of the substantially vertical bitline, the channel and the other channel, the capacitor and the other capacitor, and the wordline and the other wordline may provide a double-bit memory cell.

Device A may include a plurality of additional memory cells of the same structure as the memory cell, but elevationally above and/or below the memory cell with respective channels of the additional memory cells electrically connected to the bitline, thus providing a first column of memory cells. Another bitline may be parallel to the bitline. Device A may include a second column of memory cells of the same structure as the first column, but with respective channels electrically connected to the other bitline. The second column of memory cells includes the wordlines of the first column that extend substantially laterally with respect to the substrate along the wordlines' longest dimension from memory cells of the first column to provide wordlines in the second column, thus providing a first substantially vertical, two-dimensional array of memory cells. Device A may include a second substantially vertical, two-dimensional array of memory cells of the same structure as the first array, but parallel to the first array, thus providing a three-dimensional array of memory cells.

In such case, Device A may include a sense amplifier electrically connected to both the first and second arrays. Also, in such case, individual capacitors of the first column in the first array may substantially laterally oppose individual capacitors of a first column of memory cells in the second array. The opposing individual capacitors may include individual primary capacitor electrodes electrically isolated from one another, a single secondary capacitor electrode shared in common among the opposing individual capacitors, and a capacitor dielectric between the primary capacitor electrodes and the common secondary capacitor electrode. Further, in such case, laterally transverse wordline branches may extend at ends of the wordlines to terminate at wordline contact pads electrically connected to separate, vertical wordline contacts in turn electrically connected to separate, lateral top metal lines. The contact pads may be vertically staggered in that elevationally lower wordlines extend further along lengths of the wordlines to their ends, creating a “staircase” formation from elevationally lower to elevationally higher wordline ends. The contact pads may be laterally staggered in that the wordline branches are the longest for the furthest extending wordlines, creating a one-half “tree” formation.

The described additional features of Device A may also be implemented in other devices and methods herein.

Device B is a DRAM device including a bitline that is substantially vertical with respect to a substrate along the bitline's longest dimension. A first channel and a second channel are both at a first elevational level above and separated from the substrate on opposing sides of and electrically connected to the bitline. A first capacitor is at the first elevational level lateral from and electrically connected to the first channel and a second capacitor is at the first elevational level lateral from and electrically connected to the second channel. A first wordline and a second wordline are both at a second elevational level above and separated from the substrate on opposing sides of and electrically insulated from the bitline. The first and second wordlines are elevationally either above or below the first and second channels, respectively. A combination of the substantially vertical bitline, the first and second channels, the first and second capacitors, and the first and second wordlines provide a double-bit memory cell.

Additional features may be implemented in Device B. By way of example, the first and second capacitors may individually include a primary capacitor electrode electrically connected to the respective first or second channel, the primary capacitor electrode forming one or more container structures that have an open side. A secondary capacitor electrode may extend to within the one or more container structures. A capacitor dielectric may be between the primary and secondary capacitor electrodes.

Device B may further include a first and a second redundant wordline at a third elevational level above and separated from the substrate on the side of and electrically insulated from the bitline. The first and second redundant wordlines are opposite the respective first and second wordlines with the respective first and second channels between them.

Device B may further include a plurality of additional double-bit memory cells of the same structure as the double-bit memory cell, but elevationally above and/or below the double-bit memory cell with respective channels of the additional double-bit memory cells electrically connected to the bitline, thus providing a first column of double-bit memory cells. Another bitline is parallel to the bitline. A second column of double-bit memory cells is of the same structure as the first column, but with respective channels electrically connected to the other bitline. The second column includes the wordlines of the first column that extend substantially laterally with respect to the substrate along the wordlines' longest dimension from double-bit memory cells of the first column to provide wordlines in the second column, thus providing a first substantially vertical, two-dimensional array of double-bit memory cells. A second substantially vertical, two-dimensional array of double-bit memory cells is of the same structure as the first array, but parallel to the first array, thus providing a three-dimensional array of double-bit memory cells.

In such case, a sense amplifier may be electrically connected to both the first and second arrays. Also, in such case, individual capacitors on one side of the first column in the first array may substantially laterally oppose individual capacitors on one side of a first column of memory cells in the second array. The opposing individual capacitors may include individual primary capacitor electrodes electrically isolated from one another, a single secondary capacitor electrode shared in common among the opposing individual capacitors, and a capacitor dielectric between the primary capacitor electrodes and the common secondary capacitor electrode. Further, in such case, laterally transverse wordline branches may extend at ends of the wordlines to terminate at wordline contact pads electrically connected to separate. Vertical wordline contacts may in turn electrically connect to separate, lateral top metal lines. the contact pads may be vertically staggered in that elevationally lower wordlines extend further along lengths of the wordlines to their ends, creating a “staircase” formation from elevationally lower to elevationally higher wordline ends. The contact pads may be laterally staggered in that the wordline branches are the longest for the furthest extending wordlines, creating a “tree” formation.

The described additional features of Device B may also be implemented in other devices and methods herein.

Method C is a DRAM device forming method including forming first and second layers of channel material at respective first and second increasing elevational levels above and separated from a substrate. Method C includes simultaneously forming first and second wordlines at respective third and fourth increasing elevational levels above and separated from the substrate. A bitline is formed through the first and second layers of channel material. The bitline is substantially vertical with respect to the substrate along the bitline's longest dimension. The first and second wordlines are on a side of and electrically insulated from the bitline. First and second channels are formed from the respective first and second layers of channel material. The first and second channels are on the side of and electrically connected to the bitline. The first and second wordlines are elevationally either above or below the respective first and second channels. First and second capacitors are formed electrically connected to the respective first and second channels. A combination of the substantially vertical bitline, the first and second channels, the first and second capacitors, and the first and second wordlines provide at least a part of respective first and second memory cells, thus providing a column of memory cells.

Additional features may be implemented in Method C. By way of example, the first and second channels may be formed simultaneously. Also, for example, the first and second capacitors may be formed simultaneously.

In such case, the first and second layers of channel material may be separated from the substrate, separated from each other, and capped by respective layers of insulative material. Forming the first and second channels and the first and second capacitors may include forming a main slot through the first and second layers of channel material and the layers of insulative material. First and second side slots may be formed opening into the main slot by selectively etching back the respective first and second layers of channel material from the main slot to a selected capacitor depth. First and second capacitor recesses may be formed that open laterally into the main slot by etching back insulative material in the respective first and second side slots to the capacitor depth. The first and second channels may be formed by etching back the respective first and second layers of channel material further from the respective first and second capacitor recesses. The first and second capacitors may be formed in the respective first and second capacitor recesses, the first and second capacitors being formed at the respective first and second elevational levels lateral from the respective first and second channels.

In such case, individual first and second capacitors may have a single fin. Instead, in such case, Method C may further include forming first and second primary electrodes of respective first and second capacitors in the respective first and second capacitor recesses and electrically connected to the respective first and second channels. The first and second primary electrodes may form respective first and second container structures that open laterally into the main slot. First and second dividers are formed within the respective first and second container structures, thus dividing the first and second container structures. Electrode material is added to the first and second primary electrodes. Multiple first container structures and multiple second container structures are formed that open laterally into the main slot. In such case, individual first and second capacitors may have multiple fins.

Simultaneous to forming the first and second wordlines, first and second redundant wordlines may be formed at respective fifth and sixth increasing elevational levels above and separated from the substrate on the side of and electrically insulated from the bitline. The first and second redundant wordlines may be opposite the respective first and second wordlines with the respective first and second channels between them.

Simultaneous to forming the first and second memory cells, first and second opposing memory cells of the same structure as the first and second memory cells may be formed at the respective first and second elevational levels on an opposing side of the bitline, thus providing first and second double-bit memory cells.

The bitline may be a first bitline and the column of memory cells may be a first column of memory cells. Method C may further include, simultaneous to forming the first bitline, forming a second bitline parallel to the first bitline. Simultaneous to forming the first column of memory cells, a second column of memory cells of the same structure as the first column may be formed, but with respective channels electrically connected to the second bitline and including the wordlines of the first column that extend substantially laterally with respect to the substrate along the wordlines' longest dimension from the memory cells of the first column to provide wordlines in the second column, thus providing a first substantially vertical, two-dimensional array of memory cells. Simultaneous to forming the first array of memory cells, a second substantially vertical, two-dimensional array of memory cells of the same structure as the first array may be formed, but parallel to the first array, thus providing a three-dimensional array of memory cells.

In such case, a sense amplifier may be formed electrically connected to both the first and second arrays. Also, in such case, individual capacitors of the first column in the first array may substantially laterally oppose individual capacitors of a first column of memory cells in the second array. The opposing individual capacitors may include individual primary capacitor electrodes electrically isolated from one another, a single secondary capacitor electrode shared in common among the opposing individual capacitors, and a capacitor dielectric between the primary capacitor electrodes and the common secondary capacitor electrode. Further, in such case, laterally transverse wordline branches may extend at ends of the wordlines to terminate at wordline contact pads electrically connected to separate, vertical wordline contacts in turn electrically connected to separate, lateral top metal lines. The contact pads may be vertically staggered in that elevationally lower wordlines extend further along lengths of the wordlines to their ends, creating a “staircase” formation from elevationally lower to elevationally higher wordline ends. The contact pads may be laterally staggered in that the wordline branches are the longest for the furthest extending wordlines, creating a one-half “tree” formation.

The described additional features of Method C may also be implemented in other devices and methods herein.

Method D is a DRAM device forming method including forming first and second layers of channel material at respective first and second increasing elevational levels above and separated from a substrate. First and second wordlines and first and second opposing wordlines are simultaneously formed both at respective third and fourth increasing elevational levels above and separated from the substrate. A bitline is formed through the first and second layers of channel material. The bitline is substantially vertical with respect to the substrate along the bitline's longest dimension. The first and second wordlines and the first and second opposing wordlines, respectively, are on opposing sides of and electrically insulated from the bitline. First and second channels and first and second opposing channels are simultaneously formed from the respective first and second layers of channel material. The first and second channels and the first and second opposing channels, respectively, are on opposing sides of and electrically connected to the bitline. The first and second wordlines are elevationally either above or below the respective first and second channels. The first and second opposing wordlines are elevationally either above or below the respective first and second opposing channels. Method D includes simultaneously forming first and second capacitors at the respective first and second elevational levels lateral from and electrically connected to the respective first and second channels and simultaneous thereto also forming first and second opposing capacitors at the respective first and second elevational levels lateral from and electrically connected to the respective first and second opposing channels. A combination of the substantially vertical bitline, the first and second channels, the first and second opposing channels, the first and second capacitors, the first and second opposing capacitors, the first and second wordlines, and the first and second opposing wordlines provide respective first and second double-bit memory cells, thus providing a column of double-bit memory cells.

Additional features may be implemented in Method D, such as those described for Devices A and B and Method C.

Although minima and maxima are listed for the above described ranges and other ranges designated herein, it should be understood that more narrow included ranges may also be desirable and may be distinguishable from prior art. Also, processing principles discussed herein may provide an additional basis for the lesser included ranges.

In compliance with the statute, the embodiments have been described in language more or less specific as to structural and methodical features. It is to be understood, however, that the embodiments are not limited to the specific features shown and described. The embodiments are, therefore, claimed in any of their forms or modifications within the proper scope of the appended claims appropriately interpreted in accordance with the doctrine of equivalents.

TABLE OF REFERENCE NUMERALS FOR FIGS.

| | |
|---|---|
| 100 | memory cell |
| 102 | bitline |
| 104 | primary capacitor electrode |
| 106 | primary capacitor electrode |
| 114 | secondary capacitor electrode |
| 124 | wordline |
| 126 | wordline |
| 134 | channel |
| 136 | channel |
| 144 | bitline arm |
| 146 | bitline arm |
| 148 | capacitor divider |
| 154 | primary capacitor electrode |
| 156 | primary capacitor electrode |
| 200 | memory cell |
| 202 | bitline |
| 204 | primary capacitor electrode |
| 206 | primary capacitor electrode |
| 214 | secondary capacitor electrode |
| 224 | wordline |
| 226 | wordline |
| 234 | channel |
| 236 | channel |
| 244 | bitline arm |
| 246 | bitline arm |
| 248 | capacitor divider |
| 254 | primary capacitor electrode |
| 256 | primary capacitor electrode |
| 264 | secondary capacitor electrode |
| 300 | memory cell |
| 306 | primary capacitor electrode |
| 400 | method |
| 402 | step |
| 404 | step |
| 406 | step |
| 408 | step |
| 410 | step |
| 500 | substrate |
| 502 | insulative material |
| 504 | channel material |
| 506 | insulative material |
| 508 | channel material |
| 510 | insulative material |
| 512 | channel material |
| 514 | insulative material |
| 516 | shallow trench isolation |
| 518 | channel isolation |
| 520 | capacitor isolation |
| 522 | bitline opening |
| 524 | gate dielectric material |
| 526 | sacrificial liner |
| 528 | isolation material |
| 530 | bitline opening |
| 532 | wordline opening |
| 534 | wordline material |
| 536 | bitline opening |
| 538 | bitline insulator |
| 540 | bitline opening |
| 542 | dummy wordline |
| 544 | main slot |
| 546 | capacitor recesses |
| 548 | side slot |
| 550 | bitline barrier |
| 552 | capacitor dielectric |
| 554 | spacer material |
| 556 | insulative material |
| 558 | capacitor dielectric |
| 560 | bitline fill |
| 562 | main slot |
| 564 | lateral width |
| 566 | lateral width |
| 568 | vertical height |
| 570 | lateral width |
| 572 | lateral length |
| 574 | lateral width |
| 576 | lateral length |
| 578 | main slot |
| 580 | main slot |
| 582 | lateral width |
| 600 | wordline |
| 602 | wordline branch |
| 604 | wordline contact |
| 606 | top metal line |
| 608 | wordline decoder |
| 610 | wordline |
| 612 | wordline branch |
| 614 | wordline contact |
| 616 | top metal line |
| 618 | 2D array |
| 620 | bitline |
| 622 | bitline contact |
| 624 | top metal line |
| 626 | sense amplifier |
| 628 | 2D array |

1. A dynamic random access memory (DRAM) device comprising:
a substrate;
a bitline that is substantially vertical with respect to the substrate along the bitline's longest dimension;
a channel at a first elevational level above and separated from the substrate and on a side of and electrically connected to the bitline;
a capacitor electrically connected to the channel;
a wordline at a second elevational level above and separated from the substrate on the side of and electrically insulated from the bitline, the wordline being elevationally either above or below the channel; and
a combination of the substantially vertical bitline, the channel, the capacitor, and the wordline providing at least a part of a memory cell.

2. The device of claim 1, wherein:
the channel has a length along a conductive path within the channel between the capacitor and the bitline when the wordline is activated;
the channel has a width transverse to the channel length; and
a channel aspect ratio of the channel width to the channel length is greater than 6.

3. The device of claim 1, wherein the capacitor is at the first elevational level lateral from the channel.

4. The device of claim 2, wherein the capacitor comprises:
a primary capacitor electrode electrically connected to the channel, the primary capacitor electrode forming one or more container structures that have an open side;
a secondary capacitor electrode that extends to within the one or more container structures; and
a capacitor dielectric between the primary and secondary capacitor electrodes.

5. The device of claim 1, further comprising a redundant wordline at a third elevational level above and separated from the substrate on the side of and electrically insulated from the bitline, the redundant wordline being opposite the wordline with the channel between them.

6. The device of claim 1, further comprising:
another channel at the first elevational level and electrically connected to the bitline;
another capacitor electrically connected to the other channel;
another wordline at the second elevational level and electrically insulated from the bitline, the other wordline being elevationally either above or below the other channel; and
a combination of the substantially vertical bitline, the channel and the other channel, the capacitor and the other capacitor, and the wordline and the other wordline providing a double-bit memory cell.

7. The device of claim 1, further comprising:
a plurality of additional memory cells of the same structure as the memory cell, but elevationally above and/or below the memory cell with respective channels of the additional memory cells electrically connected to the bitline, thus providing a first column of memory cells;
another bitline parallel to the bitline;
a second column of memory cells of the same structure as the first column, but with respective channels electrically connected to the other bitline, and including the wordlines of the first column that extend substantially laterally with respect to the substrate along the wordlines' longest dimension from memory cells of the first column to provide wordlines in the second column, thus providing a first substantially vertical, two-dimensional array of memory cells; and
a second substantially vertical, two-dimensional array of memory cells of the same structure as the first array, but parallel to the first array, thus providing a three-dimensional array of memory cells.

8. The device of claim 7, further comprising a sense amplifier electrically connected to both the first and second arrays.

9. The device of claim 7, wherein:
individual capacitors of the first column in the first array substantially laterally oppose individual capacitors of a first column of memory cells in the second array; and
the opposing individual capacitors comprise:
individual primary capacitor electrodes electrically isolated from one another;
a single secondary capacitor electrode shared in common among the opposing individual capacitors; and
a capacitor dielectric between the primary capacitor electrodes and the common secondary capacitor electrode.

10. The device of claim 7, wherein:
laterally transverse wordline branches extend at ends of the wordlines to terminate at wordline contact pads electrically connected to separate, vertical wordline contacts in turn electrically connected to separate, lateral top metal lines;
the contact pads are vertically staggered in that elevationally lower wordlines extend further along lengths of the wordlines to their ends, creating a “staircase” formation from elevationally lower to elevationally higher wordline ends; and
the contact pads are laterally staggered in that the wordline branches are the longest for the furthest extending wordlines, creating a one-half “tree” formation.

11. A dynamic random access memory (DRAM) device comprising:
a substrate;
a bitline that is substantially vertical with respect to the substrate along the bitline's longest dimension;
a first channel and a second channel both at a first elevational level above and separated from the substrate on opposing sides of and electrically connected to the bitline;
a first capacitor at the first elevational level lateral from and electrically connected to the first channel and a second capacitor at the first elevational level lateral from and electrically connected to the second channel;
a first wordline and a second wordline both at a second elevational level above and separated from the substrate on opposing sides of and electrically insulated from the bitline, the first and second wordlines being elevationally either above or below the first and second channels, respectively; and
a combination of the substantially vertical bitline, the first and second channels, the first and second capacitors, and the first and second wordlines providing a double-bit memory cell.

12-17. (canceled)

18. A dynamic random access memory (DRAM) device forming method comprising:
forming first and second layers of channel material at respective first and second increasing elevational levels above and separated from a substrate;
simultaneously forming first and second wordlines at respective third and fourth increasing elevational levels above and separated from the substrate;
forming a bitline through the first and second layers of channel material, the bitline being substantially vertical with respect to the substrate along the bitline's longest dimension and the first and second wordlines being on a side of and electrically insulated from the bitline;
forming first and second channels from the respective first and second layers of channel material, the first and second channels being at the respective first and second increasing elevational levels and on the side of and electrically connected to the bitline and the first and second wordlines being elevationally either above or below the respective first and second channels;
forming first and second capacitors electrically connected to the respective first and second channels; and
a combination of the substantially vertical bitline, the first and second channels, the first and second capacitors, and the first and second wordlines providing at least a part of respective first and second memory cells, thus providing a column of memory cells.

19. The method of claim 18, wherein the first and second channels are formed simultaneously.

20. The method of claim 18, wherein the first and second capacitors are formed simultaneously.

21. The method of claim 20, wherein the first and second layers of channel material are separated from the substrate, separated from each other, and capped by respective layers of insulative material and wherein forming the first and second channels and the first and second capacitors comprises:
forming a main slot through the first and second layers of channel material and the layers of insulative material;
forming first and second side slots opening into the main slot by selectively etching back the respective first and second layers of channel material from the main slot to a selected capacitor depth;
forming first and second capacitor recesses that open laterally into the main slot by etching back insulative material in the respective first and second side slots to the capacitor depth;
forming the first and second channels by etching back the respective first and second layers of channel material further from the respective first and second capacitor recesses; and
forming the first and second capacitors in the respective first and second capacitor recesses, the first and second capacitors being formed at the respective first and second elevational levels lateral from the respective first and second channels.

22. The method of claim 21, wherein individual first and second capacitors have a single fin.

23. The method of claim 21, further comprising:
forming first and second primary electrodes of respective first and second capacitors in the respective first and second capacitor recesses and electrically connected to the respective first and second channels, the first and second primary electrodes forming respective first and second container structures that open laterally into the main slot;
forming first and second dividers within the respective first and second container structures, thus dividing the first and second container structures;
adding electrode material to the first and second primary electrodes and forming multiple first container structures and multiple second container structures that open laterally into the main slot.

24. The method of claim 23, wherein individual first and second capacitors have multiple fins.

25. (canceled)

26. (canceled)

27. The method of claim 18, wherein the bitline is a first bitline and the column of memory cells is a first column of memory cells, further comprising:
simultaneous to forming the first bitline, forming a second bitline parallel to the first bitline;
simultaneous to forming the first column of memory cells, forming a second column of memory cells of the same structure as the first column, but with respective channels electrically connected to the second bitline, and including the wordlines of the first column that extend substantially laterally with respect to the substrate along the wordlines' longest dimension from the memory cells of the first column to provide wordlines in the second column, thus providing a first substantially vertical, two-dimensional array of memory cells; and
simultaneous to forming the first array of memory cells, forming a second substantially vertical, two-dimensional array of memory cells of the same structure as the first array, but parallel to the first array, thus providing a three-dimensional array of memory cells.

28-30. (canceled)

31. A dynamic random access memory (DRAM) device forming method comprising:
forming first and second layers of channel material at respective first and second increasing elevational levels above and separated from a substrate;
simultaneously forming first and second wordlines and first and second opposing wordlines both at respective third and fourth increasing elevational levels above and separated from the substrate;
forming a bitline through the first and second layers of channel material, the bitline being substantially vertical with respect to the substrate along the bitline's longest dimension, and the first and second wordlines and the first and second opposing wordlines, respectively, being on opposing sides of and electrically insulated from the bitline;
simultaneously forming first and second channels and first and second opposing channels from the respective first and second layers of channel material, the first channel and the first opposing channel being at the first elevational level, the second channel and the second opposing channel being at the second elevational level, the first and second channels and the first and second opposing channels, respectively, being on opposing sides of and electrically connected to the bitline, the first and second wordlines being elevationally either above or below the respective first and second channels, and the first and second opposing wordlines being elevationally either above or below the respective first and second opposing channels;
simultaneously forming first and second capacitors at the respective first and second elevational levels lateral from and electrically connected to the respective first and second channels and simultaneous thereto also forming first and second opposing capacitors at the respective first and second elevational levels lateral from and electrically connected to the respective first and second opposing channels; and
a combination of the substantially vertical bitline, the first and second channels, the first and second opposing channels, the first and second capacitors, the first and second opposing capacitors, the first and second wordlines, and the first and second opposing wordlines providing respective first and second double-bit memory cells, thus providing a column of double-bit memory cells.

32-40. (canceled)
